(19) United States
(12) Patent Application Publication
(10) Pub. No.: US 2013/0328078 A1
(43) Pub. Date: Dec. 12, 2013

(54) SMALL-SIZE LED PACKAGING STRUCTURE FOR ENHANCING LIGHT EMITTING ANGLE

(71) Applicants: PING-CHEN WU, NEW TAIPEI CITY (TW); WEI-CHUNG LIN, NEW TAIPEI CITY (TW)

(72) Inventors: PING-CHEN WU, NEW TAIPEI CITY (TW); WEI-CHUNG LIN, NEW TAIPEI CITY (TW)

(73) Assignee: UNITY OPTO TECHNOLOGY CO., LTD., NEW TAIPEI CITY (TW)

(21) Appl. No.: 13/603,674

(22) Filed: Sep. 5, 2012

(30) Foreign Application Priority Data
Jun. 8, 2012 (TW) 101120656

(51) Int. Cl. H01L 33/50; H01L 33/58

(52) U.S. Cl. 257/98; 257/E33.073; 257/E33.061

(57) ABSTRACT

A small-size LED packaging structure for enhancing a Sight emitting angle includes an opaque base and at least one light emitting chip. The light emitting chip is installed on the opaque base, and the opaque base includes a transparent sidewall disposed around the base and a concave-cup space, and the transparent sidewall is formed by a molding method, and the concave-cup space is filled with a packaging gel by a dispensing method, and the packaging gel is doped with at least one phosphor powder. Therefore, the transparent sidewall can increase the light emitting angle to 140°˜180° and reduce the amount of internal reflected light significantly to avoid the occurrence of a yellow ring phenomenon, and the phosphor powder can enhance the color manifestation and the color gamut.

### CROSS-REFERENCE TO RELATED APPLICATIONS

This non-provisional application claims priority under 35 U.S.C. §119(a) on Patent Application No(s). 101120656 filed in Taiwan, R.O.C. on Jun. 8, 2012. the entire contents of which are hereby incorporated by reference.

### BACKGROUND OF THE INVENTION

1. Field of the Invention

The present invention relates to the field of LED packaging structures, in particular to a small-size LED packaging structure for enhancing a light emitting angle to fit a wide applicability of the structure.

2. Description of the Related Art

As conventional light emitting diode (LED) is comprised, of a sheet substrate or a concave-cup shaped substrate for carrying a light emitting chip and assembled by the wire-bonding and packaging operations. Although the LED packaging structure adopting the sheet substrate has a wider light emitting angle, yet the sheet substrate cannot be dispensed directly, and a later-stage assembling process will become more complicated and incur a higher cost, and thus the conventional LED package structure is not cost-effective. In addition, a gel is a concentrated semi-fluid substance with the property that cannot be formed at a fixed area easily, so that the LED usually has a poor primary light emitting effect due to the improper gel molding, and thus affecting the overall yield rate of the LED and creating problems to the light emitting efficiency.

On the other hand, although dispensing can be applied to the concave-cup shaped substrate, the sidewalk of the concave-cup shape substrate which can be used as a dispensing area restrict the light emitting angle of the LED. In other words, some sidelights emitted from the light emitting chip are blocked by the sidewall of the concave-cup shaped substrate, and the light emitting angle of the LED is limited. Even worse, some of the aforementioned sidelights blocked by the sidewalls generate internal reflections in the LED to form a yellow ring phenomenon. In view of this problem, manufacturers attempt to reduce the amount of the aforementioned sidelights blocked by the sidewalls to increase the Sight emitting angle, wherein the LED packaging structure can adjust the distance between, the sidewalls of the concave-cup shaped substrate and the light emitting chip in accordance with the direction and angle of the original light path, of the fight emitting chip. For example, the sidewalls are designed as far as possible away from the light emitting chip, so that the sidewalls will not block, the sidelights emitted from the light emitting chip to provide a broader light emitting angle. However, the LED with such arrangement will have a relatively larger packaging structure and fail to comply with the compact design requirements of the electronic products, so that such conventional structure cannot be applied extensively in different areas. If the method of simply decreasing the height of the sidewalls is adopted, the gel will not be fixed easily to obtain a good formation, and thus affecting the light emitting efficiency of the LED adversely.

Regardless of which of the aforementioned solutions is taken, the maximum light emitting angle of the conventional LED is still limited to approximately 120° only, and the illumination range and irradiating angle are limited in the use of the LED. Therefore, it is an important and urgent subject for the present invention to increase the light emitting angle while avoiding the occurrence of the yellow ring phenomenon effectively.

### SUMMARY OF TOE INVENTION

In view of the problems of the prior art, it is a primary objective of the present invention to provide a small-size LED packaging structure for enhancing the light emitting angle, the light emitting efficiency, and the scope of applicability of the LED to satisfy the illumination requirements of a backlight source of a display device.

To achieve the aforementioned objective, the present invention provides a small-size LED packaging structure for enhancing a light emitting angle and the small-size LED packaging structure comprises an opaque base and at least one light emitting chip. The light emitting chip is installed on the opaque base, and characterized in that the opaque base includes a transparent sidewall disposed around the opaque base and a concave-cup space, and the transparent sidewall is formed by a molding method, and the concave-cup space is filled with a packaging gel by a dispensing method, and the packaging gel is doped with at least one phosphor powder. Therefore, the transparent sidewall can increase the light emitting angle to 140°˜180° without causing reflection or the occurrence of a yellow ring phenomenon.

In addition, the transparent sidewall is doped with at least one scattering powder or the transparent sidewall is made of polymethylmethacrylate (PMMA), polysilsesquioxanes or epoxy to enhance the illumination uniformity.

Wherein, the transparent sidewall is a secondary optical lens for enhancing the color expression of the light emitting chip, and the transparent sidewall can be a red, green or blue transparent object having a substantially circular are shaped cross-section.

In summation of the description above, the small-size LED packaging structure can be miniaturized to broaden the scope of applicability of the LED in different fields and achieve an easy implementation and a low manufacturing cost. In addition, the transparent sidewall is considered as a secondary optical lens capable of adjusting the original light emitting angle and the distribution of target illumination areas of the light emitting chip easily. Therefore, the present invention can be applied in backlight modules of display devices to enhance the color performance of R, G, B and achieve a wide color gamut performance of the display devices, or the present invention can be applied in illumination lamps and light sources to provide a wide-angle illumination performance.

### BRIEF DESCRIPTION OF THE DRAWINGS

FIG. 1 is a cross-sectional view of the first implementation mode of a preferred embodiment of the present invention;

FIG. 2 is a schematic view of an optical path of the first implementation mode of a preferred embodiment of the present invention;

FIG. 3 is a cross-sectional view of a second implementation mode of a preferred embodiment of the present invention;

FIG. 4 is a schematic view of an optical path of the second implementation mode of a preferred embodiment of the present invention; and

FIG. 5 is a cross-sectional view of the third implementation mode of a preferred embodiment of the present invention.

### DETAILED DESCRIPTION OF THE PREFERRED EMBODIMENTS

The technical contents of the present invention will become apparent with the detailed description of preferred embodiments and the illustration of related drawings as follows.

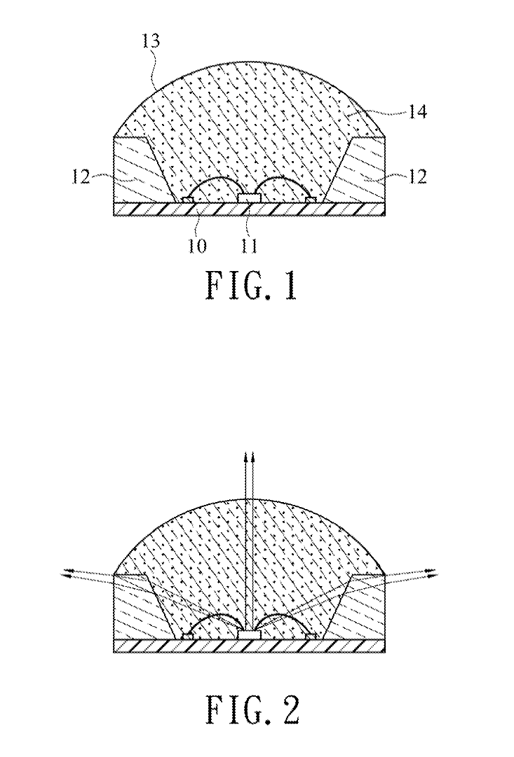

With reference to FIGS. 1 and 2 for a cross-sectional view of the first implementation mode and a schematic view of an optical path of the first implementation mode of a preferred embodiment of the present invention respectively, a small-size LED packaging structure 1 of the invention is applicable for direct backlight sources or illumination devices such as light bulbs, and the small-size LED packaging structure 1 comprises an opaque base 10 and at least one light emitting chip 11, wherein the light emitting chip 11 can be a yellow, red, blue or green LED chip, and the opaque base 10 has a transparent sidewall 12 disposed around the opaque base 10 to form a concave-cup space. The light emitting chip 11 is installed on the opaque base 10 and contained in the concave-cup space, and after the light emitting chip 11 is wire bonded and positive and negative electrodes of the opaque base 10 are electrically coupled, the concave-cup space is filled with a packaging gel 13 by a dispensing method, and the packaging gel 13 is eloped with at least one phosphor powder 14 for enhancing the physical properties and the color manifestation of the phosphor powder 14. Therefore, most sidelights emitted by the light emitting chip 11 pass through the transparent sidewall 12 and keep transmitting to the outside, and thus reducing the amount of light reflected into the concave-cup space significantly to avoid the occurrence of a yellow ring phenomenon.

It is noteworthy that the transparent sidewall 12 is formed on the opaque base 10 by a molding method. As to the light emitting chip 11, the transparent sidewall 12 can be considered as a secondary optical lens that can reduce the manufacturing cost and simplify the complicated assembling process of the illumination devices. To enhance the color manifestation of the light emitting chip 11, the transparent sidewall 12 can be doped with a dye to form a red transparent object, a green transparent object, or a blue transparent object. When the small-size LED packaging structure 1 is applied in a backlight source of a display device, the colored transparent sidewall 12 can enhance the color performance of R, G, B, so that the display device can have wide color gamut performance.

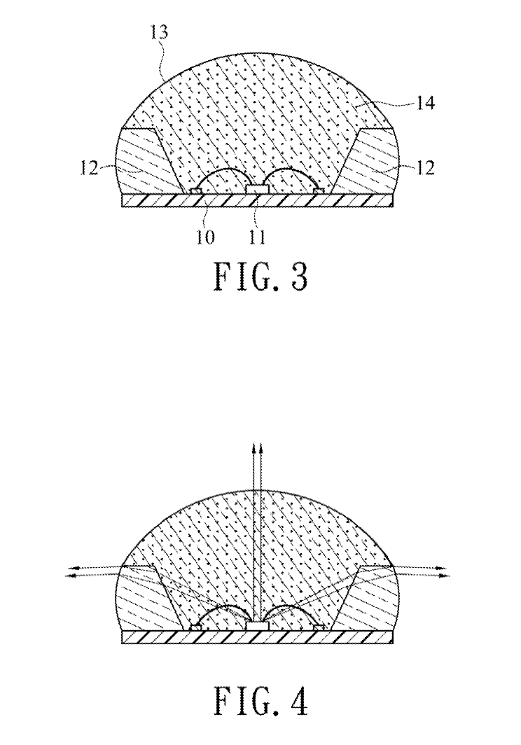

With reference to FIGS. 3 and 4 for a cross-sectional view of the second implementation mode and a schematic view of an optical path of the second implementation mode of a preferred embodiment of the present invention respectively, the transparent sidewall 12 is considered as an optical lens, and the direction of the original optical path of the light emitting chip 11 can be changed to provide a broader illumination range and improve the scope of applicability of the small-size LED packaging structure 1, so that the transparent sidewall 12 is designed with a circular arc shape cross-section, and most sidelights emitted by the light emitting chip 11 pass through the transparent sidewall 12 to produce a refraction to deflect the optical path, so as to increase the light emitting angle up to 140°˜180°. As a result, the appearance and transparency of the transparent sidewall 12 can change the light shape of the small-size LED packaging structure 1.

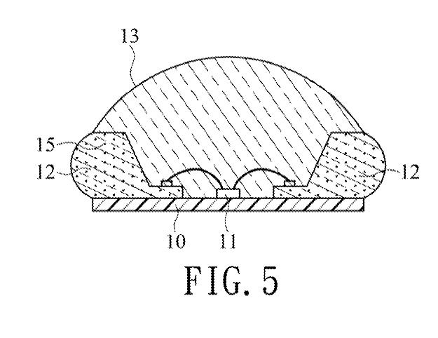

With reference to FIG. 5 for a cross-sectional view of a third implementation, mode of a small-size LED packaging structure 1 in accordance with a preferred embodiment of the present invention, the transparent sidewall 12 is doped with at least one scattering powder 15, or the transparent sidewall 12 is made of polymetbylmethacrylate (PMMA), polysilsesquioxanes or epoxy, and the scattering powder 15 is also made of polymethylmethacrylate (PMMA), polysilsesquioxanes to enhance the sidelights emitted from the light emitting chip 11. Therefore, the small-size LED packaging structure 1 has the primary optical diffusion effect without affecting the light attenuation after the packaging process is finished, and the scattering powder 15 regularly refract the point light source of the light emitting chip 11 to form a plane light source, so as to reduce the mechanical distance for converting point light source into plane light source effectively and improve the non-uniform light scattering problem.

What is claimed is:

1. A small-size LED packaging structure for enhancing a light emitting angle, having an opaque base and at least one light emitting chip, and the light emitting chip being installed on the opaque base, characterized in that the opaque base comprises a transparent sidewall disposed around the opaque base to form a concave-cup space, and the transparent sidewall is formed on the opaque base by a molding method, and the concave-cup space is filled with a packaging gel by a dispensing method, and the packaging gel is doped with at least one phosphor powder.

2. The small-size LED packaging structure of claim 1, wherein the transparent sidewall is a secondary optical lens.

3. The small-size LED packaging structure of claim 2, wherein the transparent sidewall is one selected from the collection of a red transparent object, a green transparent object, and a blue transparent object.

4. The small-size LED packaging structure of claim 3, wherein the transparent sidewall has a substantially circular arc shaped cross-section.

5. The small-size LED packaging structure of claim 1, wherein the transparent sidewall is doped with at least one scattering powder.

6. The small-size LED packaging structure of claim 5, wherein the transparent sidewall is a secondary optical lens.

7. The small-size LED packaging structure of claim 6, wherein the transparent sidewall is one selected from the collection of a red transparent object, a green transparent object, and a blue transparent object.

8. The small-size LED packaging structure of claim 7, wherein the transparent sidewall has a substantially circular arc shaped cross-section.

9. The small-size LED packaging structure of claim 1, wherein the transparent sidewall is made of a material selected from the collection of polymethylmethacrylate (PMMA), polystlsesquioxanes or epoxy.

10. The small-size LED packaging structure of claim 9, wherein the transparent sidewall is a secondary optical lens.

11. The small-size LED packaging structure of claim 10, wherein the transparent sidewall is one selected from the collection of a red transparent object, a green transparent object, and a blue transparent object.

12. The small-size LED packaging structure of claim 11, wherein the transparent sidewall has a substantially circular arc shaped cross-section.
